(19) United States
(12) Patent Application Publication
(10) Pub. No.: US 2001/0050424 A1
(43) Pub. Date: Dec. 13, 2001

(54) ELECTROSTASTIC CHARGE PROTECTION STRUCTURE

(76) Inventor: SHU-CHUAN LEE, CHANGHUA CITY (TW)

Correspondence Address: JIAWEI HUANG, J C PATENT INC, 1340 REYNOLD AVENUE, SUITE 114, IRVINE, CA, 92614

(21) Appl. No.: 09/223,407

(22) Filed: Dec. 30, 1998

(30) Foreign Application Priority Data
Jul. 16, 1998 (TW) 8711157

(51) Int. Cl. H01L 23/52

(52) U.S. Cl. 257/690

(57) ABSTRACT

An electrostatic charge protection structure, in which a conducting layer connecting the non-connected pins is added on the surface of an IC, is provided. The accumulated charges on the non-connected pins can then be attracted to the conducting layer and are discharged via the leakage capacitance between the conducting layer and the IC. Also, the conducting layer can be connected to a ground pin leading the accumulated charges to the ground. Alternatively, the conducting layer can be connected to a voltage source so that the accumulated electrostatic charges can be absorbed by the voltage source. As a result, the electrostatic charge protection structure provided in the present invention can effectively prevent the functional pins from being damaged by the ESD effect from the non-connected pins.

### CROSS-REFERENCE TO RELATED APPLICATION

This application claims the priority benefit of Taiwan application serial no. 87111578, filed Jul. 16, 1998, the full disclosure of which is incorporated herein by reference.

### BACKGROUND OF THE INVENTION

1. Field of Invention

The present invention generally relates to a protection structure for integrated circuits (IC), and more particularly to an electrostatic charge protection structure implemented to eliminate the accumulated charges on pins of integrated circuits.

2. Description of Related Art

With the steady improvement in semiconductor technologies, the dimensions of integrated circuit (IC) devices are greatly reduced thanks to higher integration density. Consequently, characteristics of small size, versatile functions, and sufficient pins have become the most salient features for an IC. In practical applications, extra pins in addition to the required functional pins are built on ICs, due to the preset pin number of the lead frame and the flexibility reserved. The functional pins are used for connection to a voltage source, ground, or signal inputs. Since an IC with a small size has many pins which are spaced closely together, damages often occur due to electrical discharge from one pin that affects neighboring pins.

As mentioned earlier, the arrangement of extra pins in an IC is a common practice during a conventional packaging process. Reference is made to FIG. 1, which shows a schematic diagram of a conventional pin configuration for an IC. For the sake of simplification, only functional pins, which comprises ground pin 110, voltage source pin 120, and input-output (I/O) pin 130, in addition to non-connected pin 140 of IC 100 are indicated, in which the ground pin 110 is connected to an electrical ground, the voltage source pin 120 is connected to a voltage source, and the I/O pin 130 can be used as an input port, output port, or input-output (I/O) port for signal input and output. As shown in FIG. 1, the ground pin 110 is connected to a bonding pad 110a, the voltage source pin 120 is connected to a bonding pad 120a, and the I/O pin 130 is connected to a bonding pad 130a within the IC 100 to obtain a desired configuration. Note that the non-connected pin 140 is not connected to any bonding pad within the IC 100. Therefore the non-connected pin 140 possesses no specific function and acts only as a backup pin.

As a result, the non-connected pin 140 will attract electrostatic charges when the IC 100 is in operation. There will be an electrostatic discharge (ESD) phenomena if the accumulated charges exceed a threshold value. Since IC's pins are densely disposed, an induced ESD stress from non-connected pins will directly affect the surrounding functional pins, often causing damage to the IC, or affecting its functional operation. Research reports have revealed that the ESD stress is rarely less than 3.5 KV. At the moment when the EDS stress occurs, a large current (for example, 1.0 to 1.7 amperes) is induced between the non-connected pin 140 and the I/O pin 130. Normally the peak current received at the I/O pin 130 is higher than that of the non-connected pin 140. Therefore, the damage caused by the ESD on the I/O pin 130 is far more serious than the non-connected pin 140. In conclusion, the ESD from the non-connected pin 140 to the I/O pin 130 results in damages to the functional pins and prevents the IC 100 from operating normally.

### SUMMARY OF THE INVENTION

It is therefore an objective of the present invention to provide an electrostatic charge protection structure for ICs to effectively eliminate the accumulated electrostatic charges on the non-connected pins. The damage to the functional pins due to the ESD stress can therefore be avoided so as to maintain a normal operation for the IC.

In accordance with the foregoing and other objectives of the present invention, an electrostatic charge protection structure is provided, in which a conducting layer connecting the non-connected pins is added on the surface of an IC. The accumulated charges on the non-connected pins can then be attracted to the conducting layer and are controllably discharged via the leakage capacitance between the conducting layer and the IC. Furthermore, the conducting layer can be connected to a ground pin leading any electrostatic charges to the ground. Alternatively, the conducting layer can be connected to a voltage source so that any electrostatic charges can be absorbed by the voltage source. Therefore, the electrostatic charges can no longer accumulate on the non-connected pins. The damage to the functional pins, for example I/O ports, due to the ESD effect from the non-connected pins can therefore be avoided to allow a normal operation for the IC.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic diagram of a conventional pin configuration for an IC;

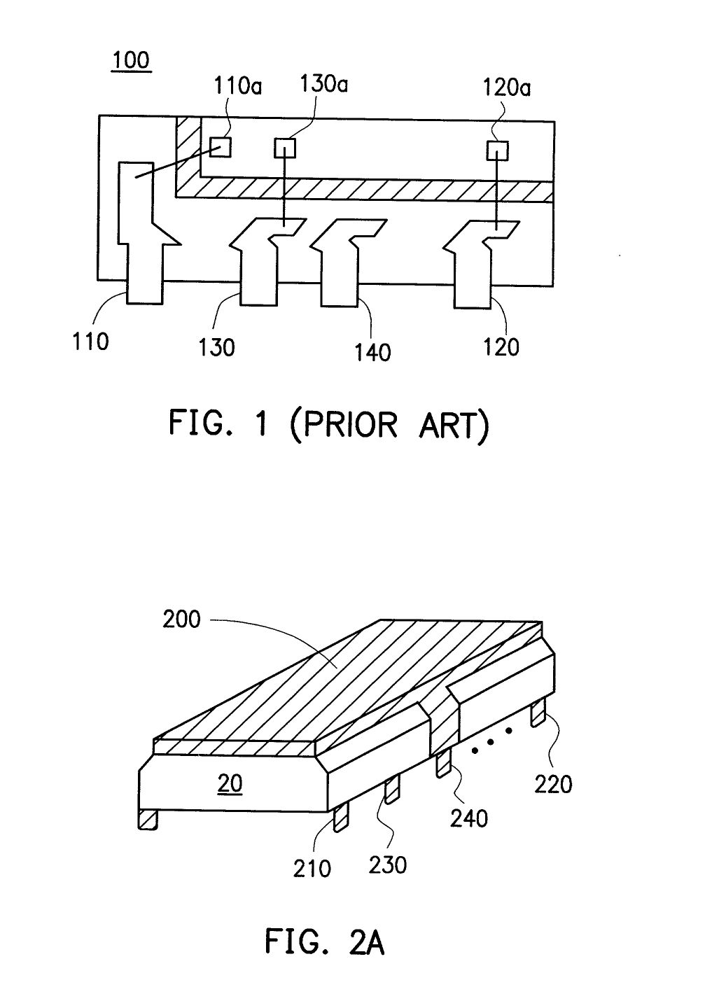

FIGS. 2A to 2C are schematic diagrams of the electrostatic charge protection structure according to a preferred embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

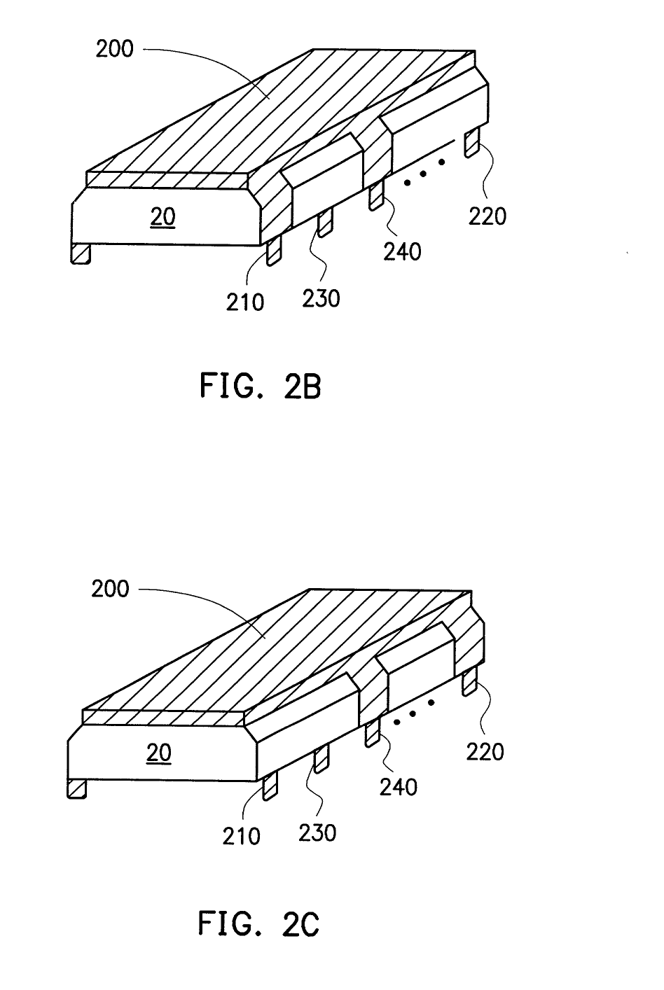

Reference is made to FIGS. 2A to 2C, which show the schematic diagrams of the electrostatic charge protection structure according to the preferred embodiment of the present invention. As shown in FIG. 2A, IC 20 comprises a conducting layer 200 on its surface, which is made from metal materials or other similar materials capable of achieving similar functions. A non-connected pin 240 is connected to the conducting layer 200. The accumulated charges on the non-connected pin 240 are conveyed to the conducting layer 200 and eliminated via the leakage capacitance between the conducting layer 200 and the IC 20. Therefore, the electrostatic charges are no longer accumulated on the non-connected pin 240 so as to avoid the damages to the functional pins, for example, the I/O pin 230, due to the ESD effect. FIG. 2B shows a similar structure where a conducting layer 200 is coupled to both a non-connected pin 240 and a ground pin 210. The accumulated charges on the conducting layer 200 are directly led to the ground pin 210 and discharged via the ground. Furthermore, the electrostatic charge protection structure can also be implemented by using a structure shown in FIG. 2C, where a conducting layer 200 is connected to both a non-connected pin 240 as well as a voltage source pin 220. Note that the voltage source pin 220 is connected to the conducting layer 200, which implies that the conducting layer 200 is connected to the voltage source. The accumulated charges on the conducting layer 200 with a higher potential are absorbed by the voltage source so as to avoid the accumulation of electrostatic charges.

As a summary, the electrostatic charge protection structure provided in the present invention can effectively prevent the electrostatic charges from accumulating on the non-connected pins. The damage to the functional pins, for example I/O ports, due to the ESD effect from the non-connected pins can therefore be avoided to allow a normal operation for an IC. The elimination of the electrostatic charges through the conducting layer is one of the most important technological characteristics in the present invention.

Although that the preferred embodiment is aimed at directing the electrostatic charges on the non-connected pins, it should not, however, be used to limit the usage of the present invention. Different pins of various ICs may be chosen for connection by those who skilled in the art using the structure of the present invention without departing from the scope or spirit of the invention should fall within the scope of the following claims and their equivalents.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An integrated circuit (IC) package having improved electrostatic discharge capabilities comprising:
a voltage source pin connected to a bonding pad within the IC package, wherein the voltage source pin is for electrical connection to a voltage source external to the IC package;
a ground pin connected to a bonding pad within the IC package, wherein the ground pin is for electrical connection to an electrical ground external to the IC package;
a signal pin connected to a bonding pad within the IC package, wherein the signal pin is for electrical connection to a signal source external to the IC package; and
a non-connected pin electrically connected to a conducting layer within the IC package.

2. The IC package of claim 1, wherein the conducting layer is electrically connected to the ground pin.

3. The IC package of claim 1, wherein the conducting layer is electrically connected to the voltage source pin.

4. An electrostatic charge protection structure for integrated circuits (IC), comprising:
a conducting layer, situated on the surface of the IC;
a non-connected pin, connected to the conducting layer, and a functional pin, connected to the conducting layer.

5. The electrostatic charge protection structure of claim 4, wherein the I/O pin is a ground pin.

6. The electrostatic charge protection structure of claim 4, wherein the functional pin is a voltage source pin.

7. The electrostatic charge protection structure of claim 4, wherein the conducting layer is made from a metal material.
